(19) United States
(12) Patent Application Publication
(10) Pub. No.: US 2013/0020567 A1
(43) Pub. Date: Jan. 24, 2013

(54) THIN FILM TRANSISTOR HAVING PASSIVATION LAYER COMPRISING METAL AND METHOD FOR FABRICATING THE SAME

(71) Applicants: Sang Yeol LEE, Seoul (KR); Eugene CHONG, Incheon (KR)

(72) Inventors: Sang Yeol LEE, Seoul (KR); Eugene CHONG, Incheon (KR)

(73) Assignee: KOREA INSTITUTE OF SCIENCE AND TECHNOLOGY, Seoul (KR)

(21) Appl. No.: 13/313,496

(22) Filed: Dec. 7, 2011

(30) Foreign Application Priority Data
Jul. 22, 2011 (KR) 10-2011-0072804

(51) Int. Cl. H01L 29/12; H01L 29/04; H01L 29/786; H01L 21/336

(52) U.S. Cl. 257/43; 438/158; 257/E29.003; 257/E29.068; 257/E29.273; 257/E21.414

(57) ABSTRACT

A thin film transistor may include a passivation layer formed of a metal-containing conductive material. The thin film transistor includes: a gate electrode; a gate insulating layer positioned on the gate electrode; a channel layer positioned on the gate insulating layer; a source electrode and a drain electrode which are in contact with the channel layer while being spaced apart from each other; and a passivation layer including a metal-containing conductive material and positioned on the channel layer while being spaced apart from each of the source electrode and the drain electrode. The passivation layer serves to prevent transmission of light, oxygen, water and/or impurities into the channel layer and to improve the electrical characteristics of the thin film transistor.

### CROSS-REFERENCE TO RELATED APPLICATION

This application claims priority to Korean patent application No. 10-2011-0072804, filed on Jul. 22, 2011, and all the benefits accruing therefrom under 35 U.S.C. §119, the contents of which in its entirety are herein incorporated by reference.

### BACKGROUND

1. Field

Embodiments relate to a thin film transistor and a method for fabricating the same. More particularly, embodiments relate to a thin film transistor having a metal-containing passivation layer and a method for fabricating the same.

2. Description of the Related Art

In general, display devices, such as organic light emitting diodes (OLEDs) or liquid crystal display (LCD), are provided with a thin film transistor (TFT) as a driving and switching element. For example, a TFT may have a bottom gate-top contact configuration including a gate electrode, a gate insulating layer on the gate electrode, a channel layer positioned on the gate insulating layer, and a source electrode and a drain electrode on the channel layer. Such TFTs may be further provided with a protective film on the top thereof.

In such TFTs, the channel layer may include silicon (Si)-containing oxide, zinc (Zn)-containing oxide or organic compounds. Particularly, a TFT having a zinc oxide (ZnO) channel layer is advantageous in that it has low power consumption, high driving performance and a high response rate. In addition, active studies have been conducted about oxide transistors having a zinc oxide channel layer due to their high cost efficiency and their simple fabrication processes, to which the conventional silicon technology is applicable.

To commercialize such oxide transistors, it is required to overcome problems related to the service life. Such oxide transistors have been limited in their applications to display devices, because they have a high oxygen transmission rate (OTR) or water vapor transmission rate (WVTR). To solve the problems, passivation has been applied to OLEDs so that the transistors are protected from permeation of water and oxygen present in the air. In general, thin film methods based on silicon oxide or organosilicon have been used as such passivation methods.

Among the materials for use in thin films that have been known to date, aluminum (Al) has been used widely as a gas barrier in the field of food and medical packaging. In addition, transparent gas barrier thin films of silicon oxide (SiOx) or aluminum oxide (AlOx) have been developed for applications in microwave ovens or in packaging ensuring visualization of contents. Recently, transparent nitride or nitrate thin films, such as those of aluminum oxynitride (AlOxNy), silicon nitride (SiNx) and silicon oxynitride (SiOxNy), have been used for passivation to facilitate realization of a low water vapor transmission rate and oxygen transmission rate.

Under these circumstances, many studies have been conducted about sputtering or plasma enhanced chemical vapor deposition (PE-CVD) processes to allow the use of transparent gas barriers of oxynitride films, such as AlOxNy, SiOxNy etc., having a more dense structure than SiOx or AlOx as passivation thin films of transistors. For example, Korean patent application publication No. 10-2007-113449 discloses forming an organic protective film including PVA, acryl or parylene on an organic semiconductor.

However, it is known that the above-mentioned gas barriers have an excessively high water vapor transmission rate so that they may not be applied to the display industry.

### SUMMARY

An aspect of the invention is directed to providing a thin film transistor having a passivation layer including a metal-containing conductive material to realize a high mobility and low resistance by using high conductivity of metal and to prevent transmission of light, oxygen, water and/or impurities permeating into oxide semiconductors, as well as a method for fabricating the thin film transistor. The passivation layer may improve characteristics of semiconductor devices.

A thin film transistor according to an embodiment may include: a gate electrode; a gate insulating layer positioned on the gate electrode; a channel layer positioned on the gate insulating layer; a source electrode and a drain electrode which are in contact with the channel layer while being spaced apart from each other; and a passivation layer including a metal-containing conductive material and positioned on the channel layer while being spaced apart from each of the source electrode and the drain electrode.

A method for fabricating a thin film transistor according to an embodiment may include: forming a gate insulating layer on a gate electrode; forming a channel layer on the gate insulating layer; forming a source electrode and a drain electrode which are in contact with the channel layer while being spaced apart from each other; and forming a passivation layer including a metal-containing conductive material and positioned on the channel layer while being spaced apart from each of the source electrode and the drain electrode.

### BRIEF DESCRIPTION OF THE DRAWINGS

The above and other aspects, features and advantages of the disclosed exemplary embodiments will be more apparent from the following detailed description taken in conjunction with the accompanying drawings in which:

FIG. 1 is a perspective view of a thin film transistor (TFT) according to an embodiment;

FIG. 2 is a sectional view of the TFT of FIG. 1 taken along line A-A′;

FIGS. 3A, 3B, 3C, 3D, and 3E are perspective views illustrating respective steps of the method for fabricating a TFT according to an embodiment;

FIGS. 4A, 4B, and 4C are perspective views illustrating respective steps for forming a channel layer, a passivation layer, and a source electrode and a drain electrode in the method for fabricating a TFT according to another embodiment;

FIG. 5 is a graph showing voltage-current characteristics of a conventional TFT; and

FIGS. 6A and 6B are graphs showing voltage-current characteristics of a TFT having a passivation layer according to an embodiment.

### DETAILED DESCRIPTION

Exemplary embodiments now will be described more fully hereinafter with reference to the accompanying drawings, in which exemplary embodiments are shown. The present disclosure may, however, be embodied in many different forms and should not be construed as limited to the exemplary embodiments set forth therein. Rather, these exemplary embodiments are provided so that the present disclosure will be thorough and complete, and will fully convey the scope of the present disclosure to those skilled in the art. In the description, details of well-known features and techniques may be omitted to avoid unnecessarily obscuring the presented embodiments.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. Furthermore, the use of the terms a, an, etc. does not denote a limitation of quantity, but rather denotes the presence of at least one of the referenced item. The use of the terms “first”, “second”, and the like does not imply any particular order, but they are included to identify individual elements. Moreover, the use of the terms first, second, etc. does not denote any order or importance, but rather the terms first, second, etc. are used to distinguish one element from another. It will be further understood that the terms “comprises” and/or “comprising”, or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the drawings, like reference numerals denote like elements. The shape, size and regions, and the like, of the drawing may be exaggerated for clarity.

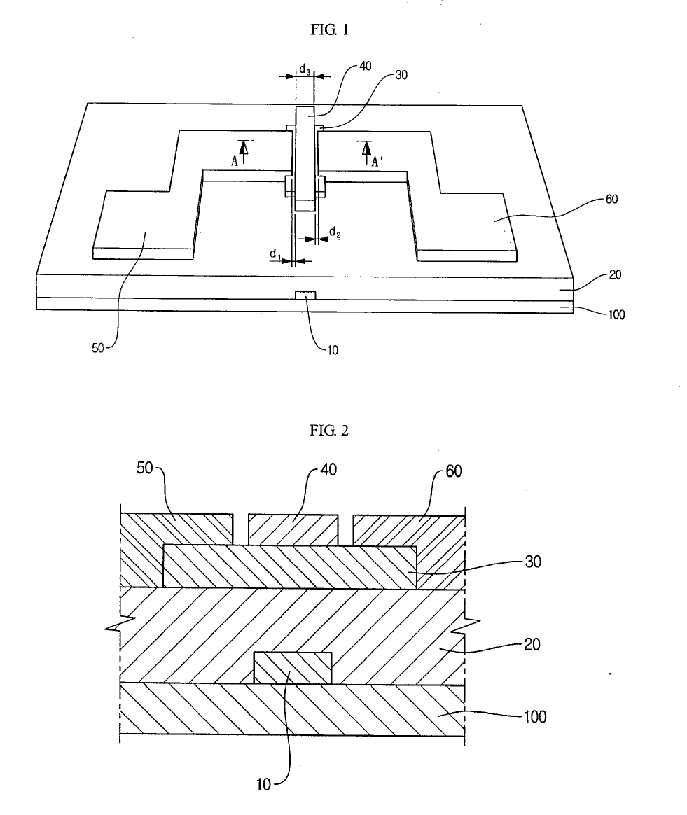

Referring to FIG. 1, the thin film transistor (TFT) according to an embodiment may include a gate electrode 10, a gate insulating layer 20, a channel layer 30, a passivation layer 40, a source electrode 50 and a drain electrode 60. In addition, the TFT according to an embodiment may include a substrate 100 on which the above elements are supported. In the TFT as shown in FIG. 1, the shape and size of each element is illustrative only, and each element of the TFT according to another embodiment may have a shape and/or size different from the shape and/or size as shown in FIG. 1.

FIG. 1 shows a bottom gate type TFT in which a gate electrode 10 and a gate insulating layer 20 are positioned below a channel layer 30. However, the TFT according to this embodiment is for illustrative purpose only. Therefore, according to another embodiment, a TFT may be realized as a top gate type TFT in which a source electrode and a drain electrode are positioned below the channel layer and the gate electrode is positioned above the channel layer. Further, in a TFT according to still another embodiment, the source electrode and the drain electrode may be positioned on different surfaces of the channel layer.

The gate electrode 10 may be positioned on a substrate 100. In an embodiment, the substrate 100 may be formed of at least one material selected from silicon (Si), glass, plastics, organic materials, polymers and other suitable materials. In an embodiment, the gate electrode 10 may be formed of metals or other conductive materials. For example, the gate electrode 10 may include any one selected from the group consisting of indium tin oxide (ITO), gallium zinc oxide (GZO), indium gallium zinc oxide (IGZO), indium gallium oxide (IGO), indium zinc oxide (IZO), silicon indium zinc oxide (Si—InZnO:SIZO) and indium oxide (In2O3), combinations thereof or other suitable materials.

The gate insulating layer 20 may be positioned on the gate electrode 10. The gate insulating layer 20 may include any one selected from the group consisting of silicon dioxide (SiO2), silicon nitride (SiNx), zirconium oxide (ZrO2), hafnium oxide (HfO2), titanium dioxide (TiO2), tantalum oxide (Ta2O5), barium-strontium-titanium-oxygen compound (Ba—Sr—Ti—O) and bismuth-zinc-niobium-oxygen compound (Bi—Zn—Nb—O), combinations thereof or other suitable materials.

The channel layer 30 may be disposed on the gate insulating layer 20. The channel layer 30 is a layer for forming a channel through which electrons move between the source electrode 50 and the drain electrode 60. The channel layer 30 may be formed of an oxide semiconductor. For example, the channel layer 30 may be formed of an oxide semiconductor having electron mobility of about 5 cm2/Vs or higher even in the case of an amorphous layer.

In an embodiment, the channel layer 30 may be formed of an oxide semiconductor containing silicon (Si) and/or zinc (Zn). In addition, the channel layer 30 may include any one selected from the group consisting of germanium (Ge), indium (In), tin (Sn), titanium (Ti), gallium (Ga), boron (B), hafnium (Hf), zirconium (Zr) and aluminum (Al), combinations thereof or other materials. For example, the channel layer 30 may be formed of SiZO (indium zinc composite oxide (InZnO) doped with silicon (Si)), zinc tin oxide (Zn—Sn—O: ZTO) and/or IGZO.

The passivation layer 40 may be disposed on the channel layer 30. The passivation layer 40 may be formed in such a manner that it partially covers the channel layer 30. The passivation layer 40 inhibits light, oxygen, water and/or other impurities from penetrating into the channel layer 30, thereby protecting the channel layer 30. In addition, the passivation layer 40 may be formed of a metal-containing conductive material. Unlike conventional TFTs using passivation with an insulating material, the passivation layer 40 of the TFT according to an embodiment of the invention is formed of a conductive material having high electron mobility, thereby improving the electrical properties of the TFT and realizing high cost-efficiency.

According to an embodiment, the passivation layer 40 may include any one selected from the group consisting of indium zinc oxide (In—ZnO), tin oxide (SnO2), zinc tin oxide (Zn—SnO), indium tin oxide (In—SnO), nickel (Ni), copper (Cu), indium (In), magnesium (Mg), tungsten (W), molybdenum (Mo), titanium (Ti), gold (Au), silver (Ag) and aluminum (Al), combinations thereof or other suitable metal-containing materials. Hereinafter, some embodiments of the invention using a passivation layer 40 including titanium (Ti) will be explained, but the material of the passivation layer 40 is not limited to titanium (Ti).

According to an embodiment, the passivation layer 40 may further include, in addition to the above-listed materials, Group I elements such as lithium (Li) or potassium (K), Group II elements such as magnesium (Mg), calcium (Ca) or strontium (Sr), Group III elements such as gallium (Ga), aluminum (Al), indium (In) or yttrium (Y), Group IV elements such as titanium (Ti), zirconium (Zr), silicon (Si), tin (Sn) or germanium (Ge), Group V elements such as tantalum (Ta), vanadium (V), niobium (Nb) or antimony (Sb), or elements of lanthanide (Ln) series such as lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb) or ruthenium (Lu).

The passivation layer 40 may have a thickness determined adequately considering the thin film characteristics of the passivation layer 40. For example, when the passivation layer 40 is too thin, light may penetrate into the passivation layer 40 and reach the channel layer 30 or the passivation layer 40 may not form a thin film well. According to an embodiment, the passivation layer 40 may have a thickness of about 4 nm or more.

In addition, the passivation layer 40 may be isolated electrically from each of the source electrode 50 and the drain electrode 60. For example, the passivation layer 40 may be spaced apart from each of the source electrode 50 and the drain electrode 60. Unlike conventional passivation layers, the passivation layer 40 includes a conductive material. Therefore, it is required for the passivation layer 40 to be isolated electrically from each of the source electrode 50 and the drain electrode 60 for the purpose of electrical insulation between the source electrode 50 and the drain electrode 60.

However, when the distance d1 between the passivation layer 40 and the source electrode 50, and the distance d2 between the passivation layer 40 and the drain electrode 60 are excessively large, the area of the channel layer 30 covered with the passivation layer 40 is decreased so that the passivation layer 40 may not function sufficiently. Therefore, the passivation layer 40 is spaced apart from each of the source electrode 50 and the drain electrode 60 in such a manner that the distance d1 between the passivation layer 40 and the source electrode 50 and the distance d2 between the passivation layer 40 and the drain electrode 60 are as small as possible. For example, the distance d1 between the passivation layer 40 and the source electrode 50, and the distance d2 between the passivation layer 40 and the drain electrode 60 each may be about 50 μm. In this case, the passivation layer 40 may have a width d3 of about 240 μm or less.

At both sides of the passivation layer 40, the source electrode 50 and the drain electrode 60 spaced apart from each other may be disposed individually in contact with the channel layer 30. In addition, the source electrode 50 and the drain electrode 60 may be disposed at least partially in contact with the gate insulating layer 20. The source electrode 50 and the drain electrode 60 may include a metal or other suitable conductive materials. For example, the source electrode 50 and the drain electrode 60 may include any one selected from the group consisting of ITO, GZO, IGZO, IGO, IZO, SIZO and In2O3, combinations thereof or other suitable materials.

According to an embodiment, one or more layers of different materials may be disposed on the passivation layer 40 to form a multi-layer film. For example, one or more layers including silicon oxide (SiOx), silicon nitride (SiNx), polymethyl methacrylate (PMMA) or other suitable materials may be disposed on the passivation layer 40.

Since the TFT as described above has a passivation layer 40 including a metal-containing conductive material and the passivation layer 40 covers the channel layer 30 including an oxide semiconductor, it has higher electron mobility and higher cost efficiency as compared to conventional TFTs. In addition, since the passivation layer 40 may be formed via a process carried out at room temperature, the TFT disclosed herein is obtained by a simple process. The TFT may be applied to various electronic devices, for example, as a driving or switching element of flat panel display such as liquid crystal display (LCD) or organic light emitting diode (OLED), or as an element forming a peripheral circuit of a memory device.

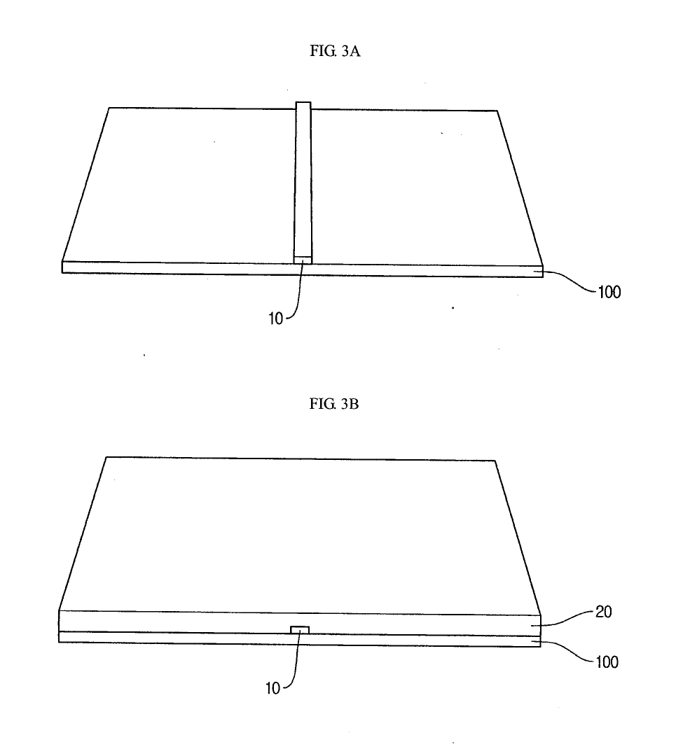

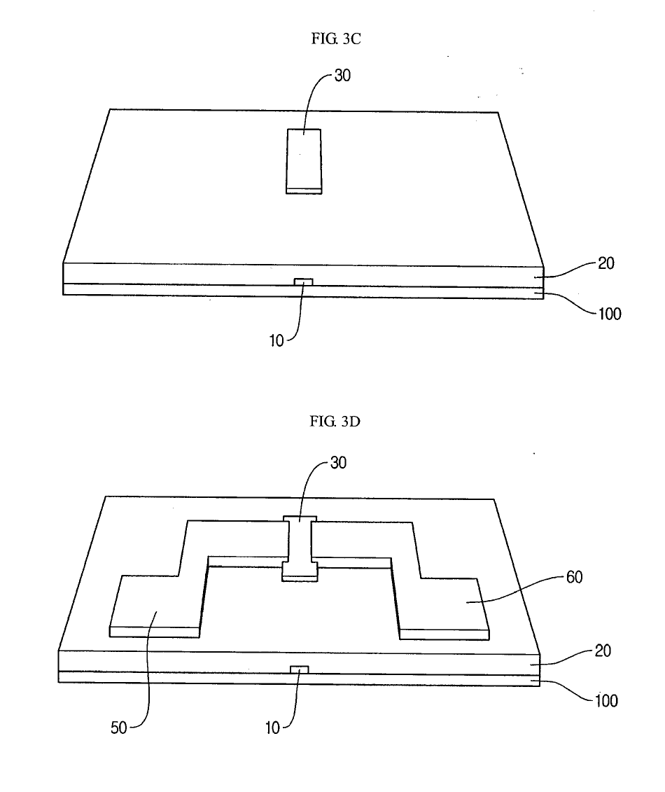

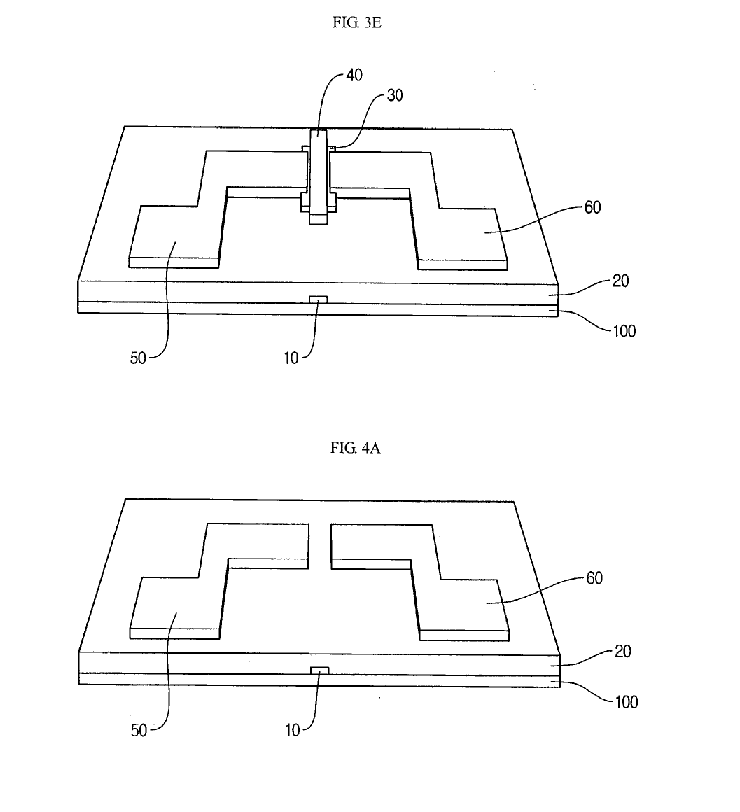

FIGS. 3A, 3B, 3C, 3D, and 3E are perspective views illustrating respective steps of the method for fabricating a TFT according to an embodiment.

Referring to FIG. 3A, a gate electrode 10 may be formed on a substrate 100. For example, the gate electrode 10 may be formed by depositing a thin film formed of a conductive material onto the substrate 100 and removing the thin film partially from the substrate via a photolithographic process, printing process and/or lift-off process.

Referring to FIG. 3B, a gate insulating layer 20 may be formed on the substrate 100 having the gate electrode 10. For example, the gate insulating layer 20 may be formed via a sputtering process, pulsed laser deposition (PLD) process, printing process or wet solution process. The gate insulating layer 20 may be formed in such a manner that it completely covers the gate insulating layer 10.

Referring to FIG. 3C, a channel layer 30 may be formed on the gate insulating layer 20. The channel layer 30 serves to form a channel region, through which electrons move, between a source electrode and a drain electrode that are formed subsequently. The channel layer 30 may include an oxide semiconductor containing silicon (Si) and/or zinc (Zn). For example, the channel layer 30 may include SIZO or IGZO.

The channel layer 30 may be formed via a PLD process, sputtering process, printing process, wet solution process or other appropriate processes. In addition, the channel layer 30 may be formed at a processing temperature of about 10° C. to about 400° C. The process for forming the channel layer 30 may be carried out under atmosphere including any one selected from the group consisting of oxygen, nitrogen and argon or a combination thereof.

Referring to FIG. 3D, a source electrode 50 and a drain electrode 60 spaced apart from each other may be formed on the substrate 100 having the gate electrode 10, gate insulating layer 20 and channel layer 30. The source electrode 50 and the drain electrode 60 may be disposed at both sides of the channel layer 30 while being in contact with the channel layer 30. The source electrode 50 and the drain electrode 60 each may be obtained by forming a thin film of a conductive material on the whole surface of the substrate 100 and partially removing the thin film via a photolithography process or lift-off process. For example, the source electrode 50 and the drain electrode 60 may be formed by using an ion beam deposition process or thermal deposition process.

Referring to FIG. 3E, a passivation layer 40 may be formed on the channel layer 30. The passivation layer 40 may be formed in such a manner that it at least partially covers the exposed portion of the channel layer 30. Meanwhile, the passivation layer 40 may be spaced apart from each of the source electrode 50 and the drain electrode 60. The passivation layer 40 may include a metal-containing conductive material.

The passivation layer 40 may be formed via a sputtering process, thermal deposition process, electron beam deposition process, chemical vapor deposition process, sol-gel process, ion plating process or other appropriate processes. In the case of an electron beam deposition process, the passivation layer 40 may be formed by allowing electron beams accelerated by an electric field or magnetic field to collide with a metal-based deposition material, thereby heating and evaporating the deposition material. Meanwhile, when the passivation layer 40 is formed via a sputtering process, it has a more dense film structure and is advantageous for crystal alignment. In addition, ion plating forms a film by ionizing particles during their evaporation. When the passivation layer 40 is formed via an ion plating process, it has good adhesion and crystallinity and enables high-speed deposition.

As described above, the passivation layer 40 may be formed via various types of processes. Particularly, the passivation layer 40 has film characteristics varied with the voltage and current applied to a deposition system, deposition temperature, oxygen flow, purity of materials, etc. Hereinafter, an exemplary embodiment in which the passivation layer 40 includes titanium (Ti) and is formed via a sputtering process will be described for illustrative purpose.

According to this embodiment, silicon dioxide (SiO2) is deposited on a p+-silicon (Si) substrate 100 as a gate insulating layer 20, IGZO-based oxide is formed on the substrate 100 as a channel layer 30, and metal electrodes are further provided thereon as a source electrode 50 and a drain electrode 60. Each of the source electrode 50 and the drain electrode 60 may have a multi-layer structure including a first layer including gold (Au) and a second layer formed on the first layer and including titanium (Ti). The first layer and the second layer may have a thickness of about 50 nm and about 10 nm, respectively.

Then, a passivation layer 40 may be deposited on the above-described structure by using a metal-containing source and target. A titanium (Ti) source is provided in a crucible of an ion beam deposition system, and titanium (Ti) is deposited on the substrate 100 in the form of a thin film by using titanium (Ti) plasma generated by ion beams under low-vacuum atmosphere. During the deposition, the substrate 100 may be rotated to obtain a uniform thin film thickness. In an embodiment, the passivation layer 40 may be deposited at room temperature. For example, the passivation layer 40 may be formed at a processing temperature of about 10° C. to about 500° C.

Then, the deposited titanium (Ti) thin film may be patterned to form the passivation layer 40. For example, the titanium (Ti) thin film is removed partially by using a lift-off process in such a manner that the passivation layer 40 at least partially covers the channel layer 30 while being spaced apart from each of the source electrode 50 and the drain electrode 60 positioned at both sides of the channel layer 30.

In the embodiment as described above, the source electrode 50 and the drain electrode 60 are formed before the passivation layer 40 is formed. However, the embodiment is illustrative only, and the passivation layer 40 may be formed before forming the source electrode 50 and the drain electrode 60 or simultaneously with the formation of the source electrode 50 and the drain electrode 60 through a single process, depending on the materials forming the passivation layer 40, source electrode 50 and drain electrode 60.

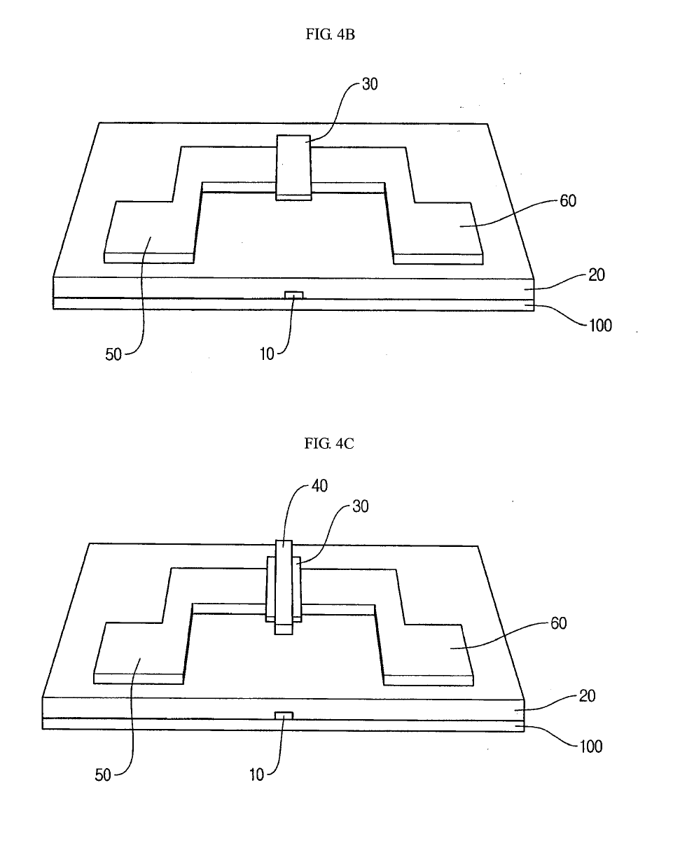

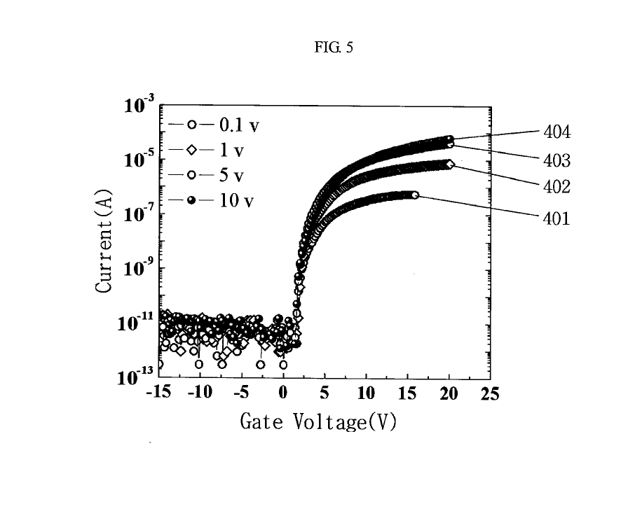

For example, FIGS. 4A, 4B, and 4C are perspective views illustrating respective steps for forming a channel layer 30, a passivation layer 40, and a source electrode 50 and a drain electrode 60 in the method for fabricating a TFT according to another embodiment.

Referring to FIG. 4A, a source electrode 50 and a drain electrode 60 may be formed on a substrate 100 having a gate electrode 10 and a gate insulating layer 20. As shown in FIG. 4A, the source electrode 50 and drain electrode 60 may be formed before forming a channel layer. Detailed description about formation of the gate electrode 10 and gate insulating layer 20 may be the same as the above-described embodiment according to FIGS. 3A and 3B, and thus will be omitted herein.

Referring to FIG. 4B, a channel layer 30 may be formed on the substrate 100 having the source electrode 50 and the drain electrode 60. The channel layer 30 may be in contact with each of the source electrode 50 and the drain electrode 60 and may be disposed between the source electrode 50 and the drain electrode 60. The channel layer 30 may also be disposed in such a manner that it covers the gate insulating layer 20 between the source electrode 50 and the drain electrode 60. In addition, the channel layer 30 may partially cover the top surfaces of the source electrode 50 and the drain electrode 60.

Referring to FIG. 4C, a passivation layer 40 may be formed on the channel layer 30. The passivation layer 40 may be formed in such a manner that it partially or entirely covers the channel layer 30.

Meanwhile, according to still another embodiment, the TFT obtained as described above may be further subjected to a heat treatment process. For example, the TFT may be heat treated at a processing temperature of about 150° C. or lower under nitrogen and/or oxygen atmosphere for about 1 hour. It is possible to improve the contact properties of the channel layer and/or the electrodes through the heat treatment process, resulting in realization of high-quality transistors.

In the method for fabricating a TFT described with reference to FIG. 3 and FIG. 4, the substrate 100, gate insulating layer 20, channel layer 30, passivation layer 40, source electrode 50 and/or drain electrode 60 each may be formed by using the same materials as those forming the corresponding part of the embodiment described above with reference to FIG. 1 and FIG. 2, and thus detailed description thereof will be omitted herein. In addition, although the method for fabricating a TFT is described hereinabove with reference to a passivation layer including titanium (Ti), other TFTs based on a passivation layer 40 including different materials may be obtained by the same method, as easily appreciated by those skilled in the art.

FIG. 5 is a graph showing voltage-current characteristics of a conventional TFT having no passivation layer. The conventional TFT has a channel layer including IGZO. In each of the four graphs 401, 402, 403, 404 in FIG. 5, y-axis represents the results of measurement of drain current when the source-drain voltage is about 0.1V (401), about 1 V (402), about 5 V (403) or about 10 V (404), and x-axis represents a gate voltage.

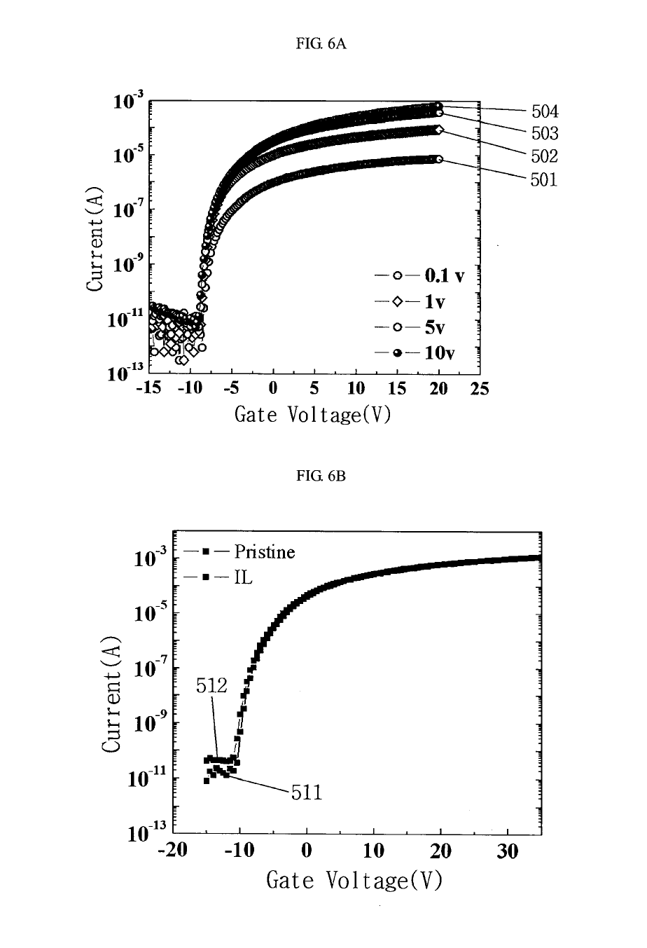

FIG. 6A is a graph showing voltage-current characteristics of a TFT having a titanium (Ti) passivation layer according to an embodiment. The TFT has a channel layer including IGZO. In each of the four graphs 501, 502, 503, 504 in FIG. 6A, y-axis represents the results of measurement of drain current when the source-drain voltage is about 0.1V (501), about 1 V (502), about 5 V (503) or about 10 V (504), and x-axis represents a gate voltage.

As can be seen from FIG. 5 and FIG. 6A, the TFT disclosed herein shows a significantly increased magnitude of current as compared to the conventional TFT having no passivation layer. This suggests that the passivation layer including a conductive material improves electron mobility. In addition, when a passivation layer including a conductive material as described herein is applied to the back channel portion of a channel layer, it is possible to improve current characteristics through the generation of built-in voltage. When applying voltage to a TFT, the TFT may be operated unstably, for example, due to electron concentration on the surface of the back channel portion of a channel layer where the channel layer is in contact with a source electrode and a drain electrode. However, when a passivation layer including a conductive material and covering the channel layer is formed at the back channel portion of the channel layer, it is possible to prevent or decrease such electron concentration by built-in voltage induced at the passivation layer having conductivity, and thus to obtain stable operation characteristics.

FIG. 6B is another graph showing voltage-current characteristics of a TFT having a titanium (Ti) passivation layer according to an embodiment. The TFT has a channel layer including SIZO. The TFT is evaluated for its reliability depending on bias temperature under an on-current state of about 10 μA. The two graphs 511, 512 in FIG. 6B show a drain current under the gate voltage measured at the initial stage of driving and at the gate voltage measured about 420 minutes after driving, respectively. As can be seen from FIG. 6B, it is possible to realize stable voltage-current characteristics even after a lapse of time from the start of driving.

As can be seen from the foregoing, the TFT according to an embodiment of the invention includes a channel layer formed of an oxide semiconductor containing zinc (Zn) and/or silicon (Si), such as silicon indium zinc oxide (Si—InZnO) or indium gallium zinc oxide (InGaZnO), and a passivation layer including a metal-containing conductive material, and thus has a high electron mobility of about 40 cm2/Vs or higher and reduces production cost as compared to conventional TFTs. In addition, the passivation layer prevents transmission of light, oxygen, water and/or impurities to the channel layer, and improves electrical properties of TFTs.

While exemplary embodiments have been shown and described, it will be understood by those skilled in the art that various changes in form and details may be made thereto without departing from the spirit and scope of the present disclosure as defined by the appended claims. In addition, many modifications can be made to adapt a particular situation or material to the teachings of the present disclosure without departing from the essential scope thereof. Therefore, it is intended that the present disclosure not be limited to the particular exemplary embodiments disclosed as the best mode contemplated for carrying out the present disclosure, but that the present disclosure will include all embodiments falling within the scope of the appended claims.

What is claimed is:

1. A thin film transistor, comprising:
a gate electrode;
a gate insulating layer positioned on the gate electrode;
a channel layer positioned on the gate insulating layer;
a source electrode and a drain electrode which are in contact with the channel layer while being spaced apart from each other; and
a passivation layer comprising a metal-containing conductive material and positioned on the channel layer while being spaced apart from each of the source electrode and the drain electrode.

2. The thin film transistor according to claim 1, wherein the passivation layer comprises at least one material selected from the group consisting of indium zinc oxide, tin oxide, zinc tin oxide, indium thin oxide, nickel, copper, indium, magnesium, tungsten, molybdenum, titanium, gold, silver and aluminum.

3. The thin film transistor according to claim 1, wherein the channel layer comprises an oxide semiconductor containing at least one of silicon and zinc.

4. A method for fabricating a thin film transistor, comprising:
forming a gate insulating layer on a gate electrode;
forming a channel layer on the gate insulating layer;
forming a source electrode and a drain electrode which are in contact with the channel layer while being spaced apart from each other; and
forming a passivation layer comprising a metal-containing conductive material and positioned on the channel layer while being spaced apart from each of the source electrode and the drain electrode.

5. The method for fabricating a thin film transistor according to claim 4, wherein the forming the passivation layer comprises forming the metal-containing conductive material via a sputtering process, thermal deposition process, electron beam deposition process, chemical vapor deposition process, sol-gel process or ion plating process.
